(19) United States
(12) Patent Application Publication
(10) Pub. No.: US 2026/0164876 A1
(43) Pub. Date: Jun. 11, 2026

(54) LIGHT-EMITTING DIODE AND LIGHT-EMITTING DEVICE

(71) Applicant: Quanzhou sanan semiconductor technology Co., Ltd., Fujian (CN)

(72) Inventors: Pengjie HU, Fujian (CN); Yuren PENG, Fujian (CN); Huanshao KUO, Fujian (CN); Weifan KE, Fujian (CN); Chun-I CHANG, Fujian (CN); Shengnan LIU, Fujian (CN); Jiayu LIU, Fujian (CN); Changjiang XU, Fujian (CN)

(73) Assignee: Quanzhou sanan semiconductor technology Co., Ltd., Fujian (CN)

(21) Appl. No.: 19/409,752

(22) Filed: Dec. 5, 2025

(30) Foreign Application Priority Data
Dec. 6, 2024 (CN) 202411793126.9

(51) Int. Cl. H10H 29/14; H10H 20/831; H10H 29/24; H10H 29/80

(52) U.S. Cl. CPC H10H 29/14; H10H 20/8314; H10H 29/24; H10H 29/8321

(57) ABSTRACT

Disclosed are a light-emitting diode and a light-emitting device. The light-emitting diode includes: a substrate, with multiple light-emitting units arranged on the surface of the substrate. Each light-emitting unit includes adjacent first and second light-emitting units. Both the first and second light-emitting units contain an epitaxial structure, which sequentially includes, from top to bottom, a first semiconductor layer, an active layer, and a second semiconductor layer. The first semiconductor layer has a first mesa, while the second semiconductor layer has an upper surface. The first light-emitting unit includes a second port, and the second light-emitting unit includes a first port. A bridging electrode connects the first light-emitting unit to the second light-emitting unit, linking adjacent first and second ports in the direction Y, and extending across the first mesa and covering a portion of the second mesa in the direction X.

### CROSS-REFERENCE TO RELATED APPLICATION

This application claims the priority benefit of China application serial No. 202411793126.9, filed on Dec. 6, 2024. The entirety of the above-mentioned patent application is hereby incorporated by reference herein and made a part of this specification.

### BACKGROUND

### Technical Field

The present disclosure involves the semiconductor-related technology, and particularly involves a light-emitting diode and a light-emitting device.

### Description of Related Art

Light-emitting diodes, also referred to as LEDs, have been commonly applied in illumination and display fields.

A high-voltage light-emitting diode (LED) is a specialized type of LED that utilizes isolation trenches to divide an epitaxial structure into several light-emitting units. Adjacent light-emitting units are then connected using bridging electrodes.

In current processes, the bridging electrodes typically connect adjacent light-emitting units in series in a single direction, i.e., a direction in which the adjacent light-emitting units are arranged. However, during die bonding and use of the light-emitting diode, a metal surface of the bridging electrode may be easily damaged, leading to short-circuit failure, which seriously affects the reliability of the high-voltage light-emitting diode. Therefore, how to improve the reliability of the high-voltage light-emitting diode has become an urgent problem to be solved.

### SUMMARY

The present disclosure provides a light-emitting diode and a light-emitting device to solve at least one of the above problems.

In a first aspect, the present disclosure provides a light-emitting diode, including:
A substrate, including an upper surface;
Wherein a plurality of light-emitting units are disposed on the upper surface of the substrate, the light-emitting units contain a first light-emitting unit and a second light-emitting unit adjacent to each other, an isolation trench is formed between the first light-emitting unit and the second light-emitting unit, the first light-emitting unit to the second light-emitting unit are arranged in a direction Y, and a direction perpendicular to the direction Y is a direction X;
The first light-emitting unit and the second light-emitting unit both contain an epitaxial structure, the epitaxial structure sequentially includes, from top to bottom, a first semiconductor layer, an active layer, and a second semiconductor layer;
The first semiconductor layer has an upper surface, which is a first mesa;
The second semiconductor layer has an upper surface, and a portion of the upper surface of the second semiconductor layer not covered by the first semiconductor layer and the active layer is a second mesa;
The first light-emitting unit further contains a first electrode and a second port, the first electrode is disposed on the first mesa, and the second port is disposed on the second mesa;
The second light-emitting unit further contains a second electrode and a first port, the second electrode is disposed on the second mesa, and the first port is disposed on the first mesa;
A bridging electrode connects the first light-emitting unit and the second light-emitting unit, the bridging electrode connects the first port and the second port adjacent to each other along the direction Y;
In the second light-emitting unit, the bridging electrode passes through the first mesa along the direction X and covers a portion of the second mesa, and a portion of the bridging electrode covering the second mesa is an extension portion of the bridging electrode.

In a second aspect, the present disclosure further provides a light-emitting device, including the above-mentioned light-emitting diode.

The light-emitting diode provided by the present disclosure has a bridging electrode. The bridging electrode not only electrically connects the first light-emitting unit and the second light-emitting unit in the direction Y (the arrangement direction from the first light-emitting unit to the second light-emitting unit), but also passes through the first mesa of the second light-emitting unit in the direction X (the direction perpendicular to the direction Y), and covers a portion of the second mesa of the second light-emitting unit. Therefore, the bridging electrode is equivalent to having two current paths on the second light-emitting unit. One path may communicate with the first light-emitting unit along the direction Y from the first mesa of the second light-emitting unit, and another path may communicate with the first light-emitting unit along the direction Y from the second mesa of the second light-emitting unit, thereby significantly reducing the possibility of short-circuit failure of the bridging electrode and dramatically improving the reliability of the light-emitting diode.

The light-emitting device provided by the present disclosure includes the above-mentioned light-emitting diode, and therefore also has the above-mentioned advantages.

### BRIEF DESCRIPTION OF THE DRAWINGS

FIG. 1 is a top view of a conventional light-emitting diode;

FIG. 2 is a cross-sectional view of Embodiment 1 of the present disclosure;

FIG. 3 is a top view of Embodiment 1 of the present disclosure;

FIG. 4 is a top view further showing an extension portion of a bridging electrode based on FIG. 3 in Embodiment 1 of the present disclosure;

FIG. 5 is a top view further illustrating structural parameters based on FIG. 3 and FIG. 4 in Embodiment 1 of the present disclosure;

FIG. 6 is a cross-sectional view taken along a direction AA′ based on FIG. 4 in Embodiment 1 of the present disclosure;

FIG. 7 is a cross-sectional view taken along a direction BB′ based on FIG. 4 in Embodiment 1 of the present disclosure;

FIG. 8 is a top view supplemented with bond pad electrodes in Embodiment 1 of the present disclosure;

FIG. 9 is a top view of a light-emitting diode according to an Embodiment 2 of the present disclosure;

FIG. 10 is a cross-sectional view of a light-emitting device according to Embodiment 3 of the present disclosure.

### DESCRIPTION OF THE EMBODIMENTS

The embodiment of the present disclosure is described below through specific embodiments. Those skilled in the art may easily understand other advantages and effects of the present disclosure from the content disclosed in this specification. The present disclosure may also be implemented or applied through other different specific embodiments, and various details in this specification may also be modified or changed based on different viewpoints and applications without departing from the spirit of the present disclosure. It should be noted that, in the case of no conflict, the following embodiments and features in the embodiments may be combined with each other.

It should be noted that the illustrations provided in the embodiments of the present disclosure only illustrate the basic concept of the present disclosure in a schematic manner. Although the illustrations only show components related to the present disclosure rather than being drawn according to the number, shape and size of components in actual embodiment, the form, quantity and proportion of each component in actual embodiment may be changed at will, and the component layout form may also be more complex. The structures, proportions, sizes, etc. depicted in the accompanying drawings of the specification are only used to cooperate with the content disclosed in the specification for understanding and reading by those familiar with this technology, and are not used to limit the limiting conditions under which the present disclosure may be implemented, so they have no substantial technical significance. Any modification of structure, change of proportional relationship or adjustment of size, without affecting the efficacy that the present disclosure may produce and the purpose that may be achieved, should still fall within the range that the technical content disclosed in the present disclosure may cover.

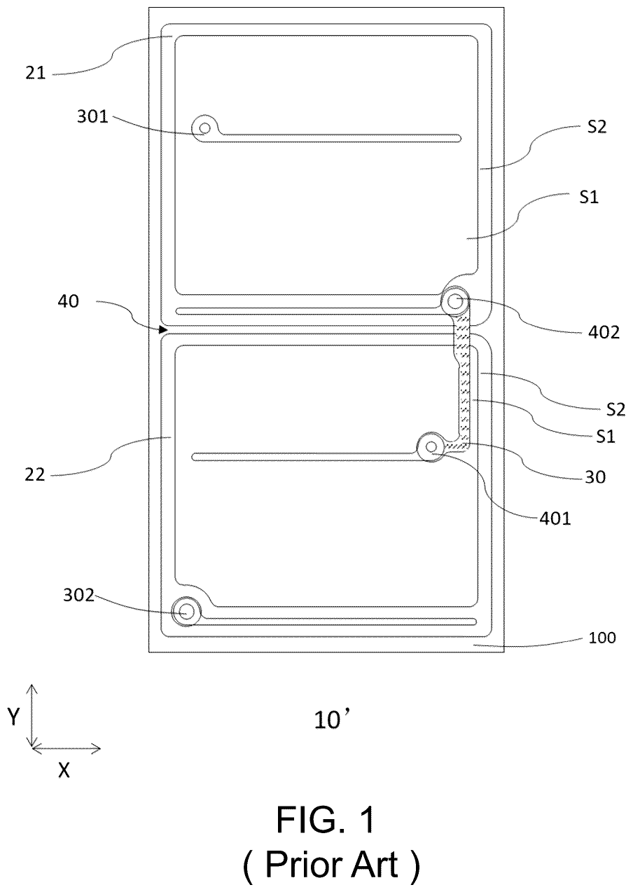

As shown in FIG. 1, an existing high-voltage light-emitting diode 10′includes a plurality of light-emitting units. The light-emitting units include a first light-emitting unit 21 and a second light-emitting unit 22 adjacent to each other. The first light-emitting unit 21 to the second light-emitting unit 22 are arranged in a direction Y, and the first light-emitting unit 21 and the second light-emitting unit 22 are spaced apart from each other through an isolation trench 40. A bridging electrode 30 connects the first light-emitting unit 21 and the second light-emitting unit 22 adjacent to each other along the direction Y, so that the first light-emitting unit 21 and the second light-emitting unit 22 are electrically connected to each other. For existing high-voltage light-emitting diodes, the bridging electrode only connects adjacent light-emitting units in series in a single direction (the direction Y in the figure), that is, the direction in which the adjacent light-emitting units are arranged. However, during die bonding and use of the light-emitting diode, a metal surface of the bridging electrode 30 may be easily damaged, leading to a short-circuit failure of the bridging electrode with only a single conduction path, which seriously affects the reliability of the high-voltage light-emitting diode.

In order to solve the above problems, the inventors, through experimental design and verification, invented a light-emitting diode, including:
A substrate, including an upper surface; wherein a plurality of light-emitting units are disposed on the upper surface of the substrate, the light-emitting units contain a first light-emitting unit and a second light-emitting unit adjacent to each other, an isolation trench is formed between the first light-emitting unit and the second light-emitting unit, the first light-emitting unit to the second light-emitting unit are arranged in a direction Y, and a direction perpendicular to the direction Y is a direction X;
The first light-emitting unit and the second light-emitting unit both contain an epitaxial structure, the epitaxial structure sequentially includes, from top to bottom, a first semiconductor layer, an active layer, and a second semiconductor layer in sequence;
The first semiconductor layer has an upper surface, which is a first mesa;
The second semiconductor layer has an upper surface, and a portion of the upper surface of the second semiconductor layer not covered by the first semiconductor layer and the active layer is a second mesa;
The first light-emitting unit further contains a first electrode and a second port, the first electrode is disposed on the first mesa, and the second port is disposed on the second mesa;
The second light-emitting unit further contains a second electrode and a first port, the second electrode is disposed on the second mesa, and the first port is disposed on the first mesa;
A bridging electrode connects the first light-emitting unit and the second light-emitting unit, the bridging electrode connects the first port and the second port adjacent to each other along the direction Y;
In the second light-emitting unit, the bridging electrode passes through the first mesa along the direction X and covers a portion of the second mesa, and a portion of the bridging electrode covering the second mesa is an extension portion of the bridging electrode.

Optionally, a horizontal projection area of the extension portion of the bridging electrode on the second mesa accounts for 0.8% to 15% of a horizontal projection area of the second mesa.

Optionally, the second mesa where the extension portion of the bridging electrode is located has a width D in the direction X, the extension portion of the bridging electrode has a width d in the direction X, and a ratio of the width d to the width D ranges from 60% to 90%.

Optionally, the extension portion of the bridging electrode has a width d in the direction X, and the width d ranges from 4μm to 60μm.

Optionally, the second mesa where the extension portion of the bridging electrode is located has a width D in the direction X, and the width D ranges from 6 μm to 70 μm.

Optionally, a portion of the bridging electrode at the first mesa of the second light-emitting unit has a minimum width W in the direction X, and the minimum width W ranges from 1 μm to 30 μm.

Optionally, the isolation trench has a width g in the direction Y, and the width g ranges from 3 μm to 30 μm.

Optionally, the extension portion of the bridging electrode has a length L1 in the direction Y, and the length L1 ranges from 5 μm to 95 μm.

Optionally, the bridging electrode has a length L2 in the direction Y, and the length L2 ranges from 18 μm to 110 μm.

Optionally, the second light-emitting unit has a first sidewall between the first mesa and the second mesa, an angle α is formed between the first sidewall and a horizontal plane, and the angle α ranges from 35° to 75°.

Optionally, the extension portion of the bridging electrode has a thickness h1 on the second mesa, and the thickness h1 ranges from 0.5 μm to 8 μm.

Optionally, a second sidewall is provided between the second mesa of the second light-emitting unit and the isolation trench, an angle β is formed between the second sidewall and the horizontal plane, and the angle β ranges from 50° to 85°.

Optionally, the bridging electrode has a thickness h2 on the isolation trench, and the thickness h2 ranges from 0.5 μm to 8 μm.

Optionally, the light-emitting diode has 1 pair or 2 pairs of first light-emitting units and second light-emitting units adjacent to each other.

Optionally, a bonding layer is further disposed on the substrate.

Optionally, an insulating layer is disposed outside the epitaxial structure, and the insulating layer is a single-layer or multi-layer structure.

Optionally, a first bond pad is disposed on the first electrode, and a second bond pad is disposed on the second electrode.

Optionally, the first electrode and/or the second electrode have an expanding portion.

Optionally, a material of the bridging electrode is one of Ti, Pt, Au, or a combination of at least two of the above.

The present disclosure also provides a light-emitting device, including the above-mentioned light-emitting diode.

The present disclosure will be described in detail below in conjunction with specific embodiments.

### Embodiment 1

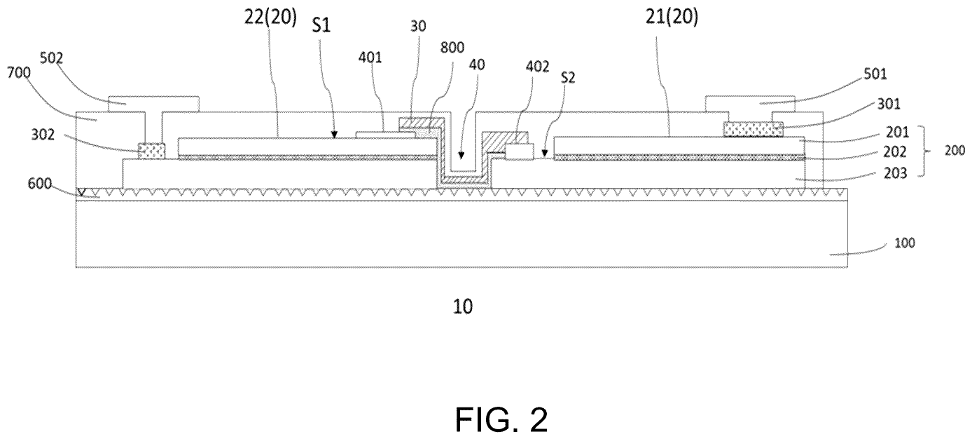

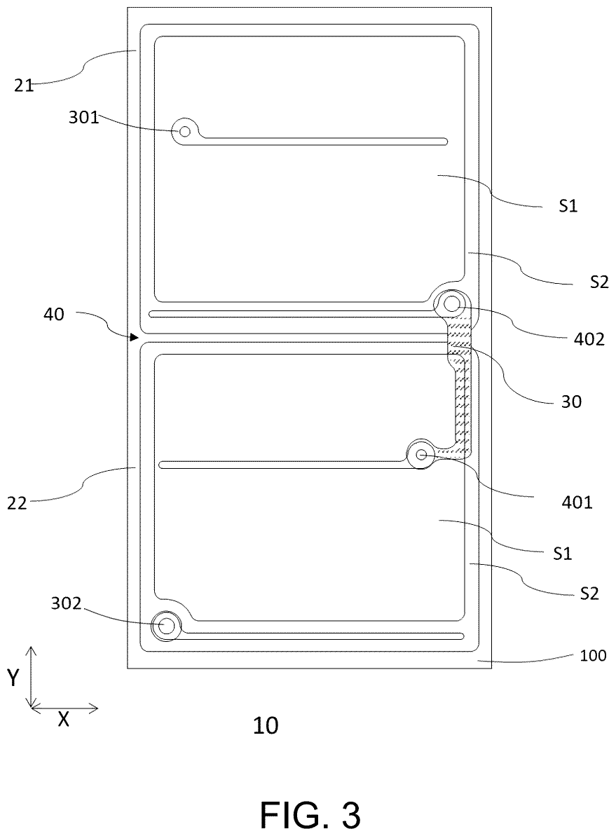

The present embodiment provides a light-emitting diode. Referring to FIG. 2 and FIG. 3, a plurality of light-emitting units 20 are disposed on a substrate 100, such as a first light-emitting unit 21 and a second light-emitting unit 22. The two light-emitting units 20 are adjacent to each other and are separated by an isolation trench 40. A direction in which the first light-emitting unit 21 and the second light-emitting unit 22 are arranged is defined as a direction Y, and a direction perpendicular to the direction Y is defined as a direction X. It should be noted that the directions X and Y herein are only set for facilitating understanding of the present disclosure, and are not actual arrangement directions. The substrate 100 may be sapphire, silicon substrate, silicon carbide, etc. In the present embodiment, sapphire is selected.

The first light-emitting unit 21 and the second light-emitting unit 22 both contain an epitaxial structure 200. The epitaxial structure 200 sequentially includes, from top to bottom, a first semiconductor layer 201, an active layer 202, and a second semiconductor layer 203. The first semiconductor layer 201 may be an N-type semiconductor layer, the active layer 202 may be a multiple quantum well layer, which may provide red light or infrared light radiation, and the second semiconductor layer 203 may be a P-type semiconductor layer. The N-type semiconductor layer, the multiple quantum well layer, and the P-type semiconductor layer are only basic units for constituting the semiconductor stacked layer. On this basis, the semiconductor stacked layer may also include other functional structure layers that have an optimizing effect on the performance of the light-emitting diode, such as an ohmic contact layer or a current spreading layer. In the present implement, the light-emitting diode is preferably a flip-chip light-emitting diode, and is preferably a red light diode or an infrared light diode.

An upper surface of the first semiconductor layer 201 is a first mesa S1, and a portion of an upper surface of the second semiconductor layer 203 not covered by the first semiconductor layer 201 or the active layer 202 is a second mesa S2.

A first electrode 301 is disposed on the first mesa S1 of the first light-emitting unit 21, and a second port 402 is disposed on the second mesa S2 of the first light-emitting unit 21. The second port 402 may be electrically connected with the second semiconductor layer 203, and may serve as a bonding point of the bridging electrode 30 on the first light-emitting unit 21. In the present implement, the first electrode 301 is a negative electrode, and the second port 402 is a positive electrode.

A second electrode 302 is disposed on the second mesa S2 of the second light-emitting unit 22, and a first port 401 is disposed on the first mesa S1 of the second light-emitting unit 22. The first port 401 may be electrically connected with the first semiconductor layer 201, and may serve as a bonding point of the bridging electrode 30 on the second light-emitting unit 22. In the present implement, the second electrode 302 is a positive electrode, and the first port 401 is a negative electrode.

In the present implement, the first port 401 and the first electrode 301 are negative electrodes, and a material for the first port 401 and the first electrode 301 is selected from one or more alloys or combinations of Au, Pt, Ti, Ge, and Ni. The second port 402 and the second electrode 302 are positive electrodes, and a material thereof is selected from one or more alloys or combinations of Au, Be, Ti, and Pt.

The bridging electrode 30 connects the first port 401 and the second port 402. As shown in FIG. 3, the bridging electrode 30 passes over the isolation trench 40 in the direction Y, electrically connecting the first light-emitting unit 21 and the second light-emitting unit 22. In the present embodiment, a material of the bridging electrode 30 is an alloy comprising one or more of the following: Ti, Pt, Au, and Al, or combinations thereof.

Compared with the bridging electrode 30 of the conventional light-emitting diode (as shown in FIG. 1), in the present implement, the bridging electrode 30 is arranged relatively to the right, so that the bridging electrode 30 passes through the first mesa S1 of the second light-emitting unit 22 in the direction X and covers a portion of the second mesa S2. In this way, the bridging electrode 30 may not only conduct electricity at the first mesa S1, but also transmit current at the second mesa S2. When the bridging electrode 30 on the S1 mesa is damaged, the bridging electrode 30 may still perform transmission to the second mesa S2 through the sidewall and continue to complete current transmission, which is equivalent to having an additional current transmission channel than the conventional light-emitting diode, thus significantly improving the reliability of the light-emitting diode.

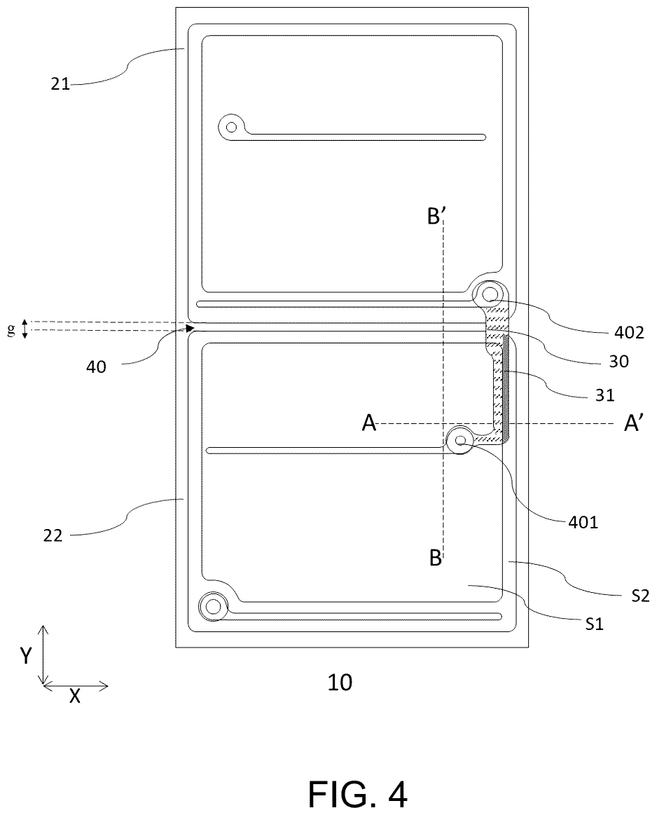

As shown in FIG. 4, the bridging electrode 30 passes through the first mesa S1 along the direction X and covers a portion of the second mesa S2, and a portion covering the second mesa S2 (the gray shaded portion in the bridging electrode) is an extension portion 31 of the bridging electrode.

In some embodiments, a horizontal projection area of the extension portion 31 of the bridging electrode on the second mesa S2 accounts for 0.8% to 15% of an area of the second mesa S2. If this area is too small, it might be difficult to carry out effective current transmission on the second mesa S2; if this area is too large, the remaining portion of the bridging electrode 30 on the first mesa S1 will be too small, which will affect the transmission carried out by the bridging electrode 30 on the first mesa S1. In the present embodiment, this area ratio is set to be from 3% to 8%.

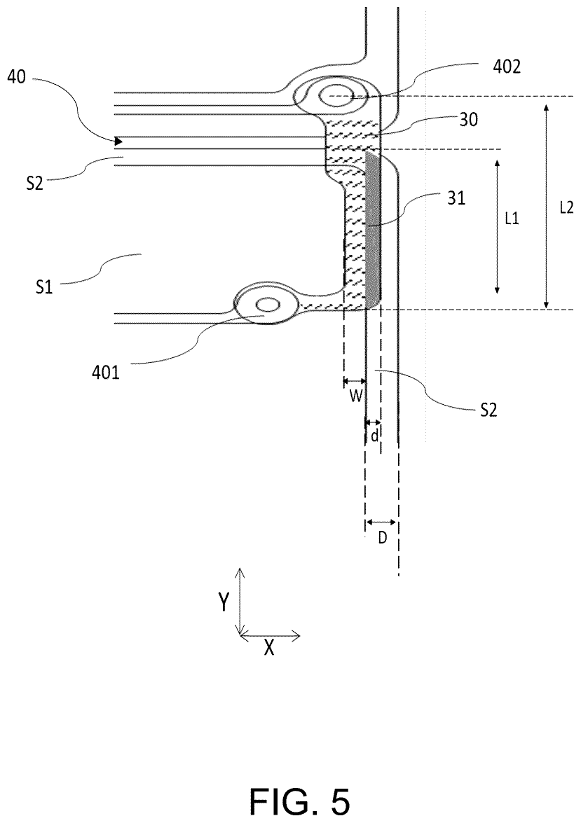

As shown in FIG. 5, the extension portion 31 of the bridging electrode has a width d in the direction X. In some embodiments, the width d ranges from 4 μm to 60 μm. If the width d is less than 4 μm, the extension portion 31 of the bridging electrode is too narrow, and it is difficult for current to be effectively transmitted on the second mesa S2. If the width d is greater than 60 μm, the transmission of the current on the first mesa S1 might be affected, and voltage problems are likely to occur. In the present embodiment, the width d ranges from 5 μm to 25 μm.

The second mesa S2 at the extension portion 31 of the bridging electrode also has a width D in the direction X, the width D is a lateral (direction X) spacing between an edge of the first mesa S1 and an edge of the second mesa S2. In some embodiments, the width D ranges from 6 μm to 70 μm, and this value affects the difficulty of setting the bridging electrode 31 between the first mesa S1 and the second mesa S2. In the present embodiment, the width D ranges from 10 μm to 40 μm.

In some embodiments, a ratio d/D of the width d to the width D ranges from 60% to 90%. This range may ensure that the extension portion 31 of the bridging electrode has a suitable area ratio, as well as a suitable current channel, and does not affect the current transmission carries out by the bridging electrode 30 on the first mesa S1.

A portion (i.e., the portion of the bridging electrode 30 at the second light-emitting unit 22 excluding the extension portion 31 of the bridging electrode) of the bridging electrode 30 at the first mesa S1 of the second light-emitting unit 22 has a minimum width W in the direction X. In some embodiments, W ranges from 1μm to 30μm. The value of this portion represents the minimum portion of the bridging electrode 31 at the first mesa S1 of the second light-emitting unit 22. That is, if this range is too small (e.g., W is less than 1μm), it indicates that the bridging electrode 31 is offset too much to the right, with most of it falling onto the second mesa S2, which is unfavorable for current transmission carried out by the bridging electrode 30 on the first mesa S1, and may easily cause the extension portion 31 of the bridging electrode to be too large, potentially extending beyond the second mesa S2 and causing voltage problems as well as ESD problems. If this range is too large (e.g., W is greater than 30 μm), the current will be predominantly distributed across the portion of the bridging electrode 31 at the first mesa S1, leaving only a minimal portion of the extension portion 31 of the bridging electrode, meaning that only a small amount of current may be transmitted at the second mesa S2, which is unfavorable for the light-emitting performance of the high-voltage light-emitting diode and poses challenges in preventing short-circuit problems. In the present embodiment, W ranges from 1 μm to 20 μm.

As shown in FIG. 4, the first light-emitting unit 21 and the second light-emitting unit 22 are separated by the isolation trench 40, where no epitaxial structure is present at the isolation trench 40, thus being unable to conduct electricity. The isolation trench 40 may be an exposed substrate or may be another oxide insulating layer. In some embodiments, the isolation trench has a width g in the direction Y, and the width g ranges from 3 μm to 30 μm. If the range is too small, it is unfavorable for the arrangement of the light-emitting units 20, the process difficulty is high, and it may also cause the metal deposited on the sidewall of the bridging electrode 30 to be too thin, which is likely to cause short-circuit issues. If the range is too large, it may cause the area of the light-emitting diode 10 to be too large, and the bridging electrode 30 has to be increased in length, which is likely to cause ESD or other voltage problems. In the present embodiment, the width g ranges from 3 μm to 25 μm.

As shown in FIG. 5, the extension portion 31 of the bridging electrode has the length L1 in the direction Y, and the bridging electrode 30 has the length L2 in the direction Y. In some embodiments, the length L1 ranges from 5 μm to 95 μm. Same as the above, the range of the width d may ensure the width of the extension portion 31 of the bridging electrode, and the range of the length L1 ensures the length of the extension portion 31 of the bridging electrode, and the length L1 within a suitable range contributes to the transmission of current on the second mesa S2. In the present embodiment, the length L1 ranges from 5 μm to 85 μm

In some embodiments, the length L2 ranges from 18 μm to 110 μm. In the present embodiment, the length L2 preferably ranges from 30 μm to 90 μm.

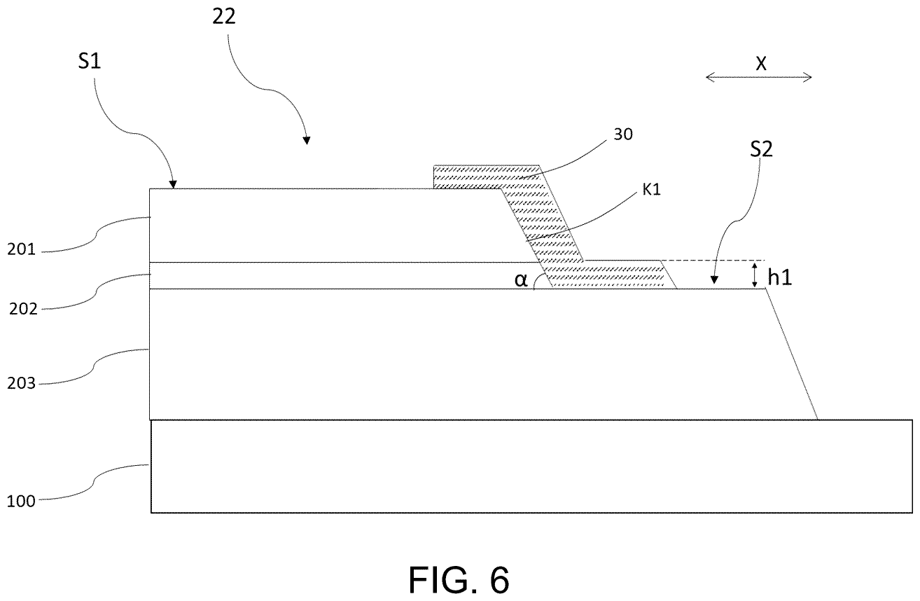

According to a line taken along a direction AA′ in FIG. 4, a cross-sectional view of FIG. 6 may be obtained. As shown in FIG. 6, a first sidewall K1 is provided between the first mesa S1 and the second mesa S2 of the second light-emitting unit 22, and an angle α is formed between the sidewall K1 and the horizontal plane. In some embodiments, the angle α ranges from 35° to 75°. The range of the angle affects the coverage of the bridging electrode 30 on the second mesa S2. For example, when the bridging electrode 30 is evaporated, if the first sidewall K1 is too steep, for example, α>75°, the bridging electrode 30 may not cover and connect well at the first sidewall K1, which may easily cause the bridging electrode 30 at the first mesa S1 and the bridging electrode 30 at the second mesa S2 to break, causing failure to work normally; if the first sidewall K1 is too gradual, for example, α<30°, it is likely for the bridging electrode 30 to cover mostly at the first sidewall K1 and may not be deposited onto the second mesa S2, affecting the reliability of the light-emitting diode. In the present embodiment, the angle α ranges from 40° to 70°.

The extension portion 31 of the bridging electrode has the thickness h1 on the second mesa S2. In some embodiments, the thickness h1 ranges from 0.5 μm to 8 μm. If the thickness h1 is too thin, it might be difficult to carry out effective current transmission. If the thickness h1 is too thick, it is likely to cause significant variations in the surface level of chips, while also substantially increase the complexity and cost of the manufacturing process. In the present embodiment, the thickness h1 ranges from 1.5 μm to 3 μm.

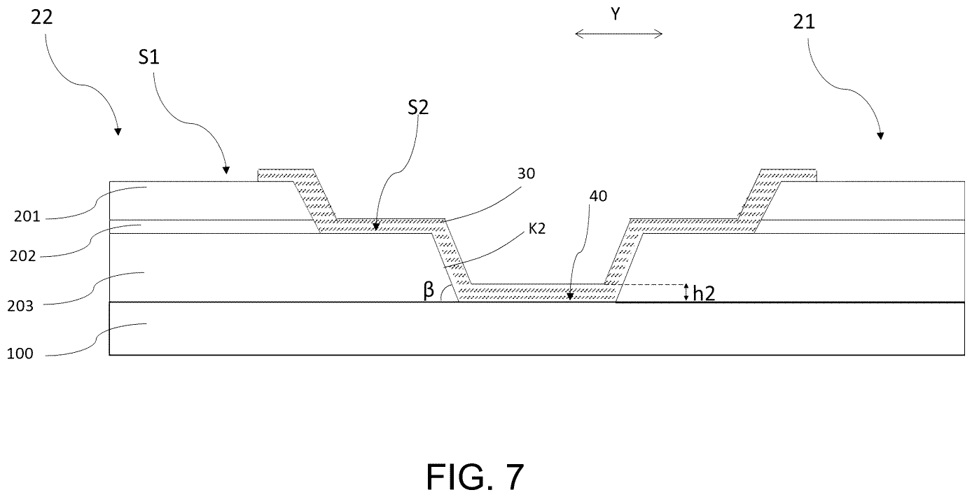

According to a line taken along a direction BB′ in FIG. 4, a cross-sectional view of FIG. 7 may be obtained. As shown in FIG. 7, a second sidewall K2 is provided between the second mesa S2 of the second light-emitting unit 22 and the isolation trench 40. An angle β is formed between the second sidewall K2 and the horizontal plane. In some embodiments, the angle β ranges from 50° to 85°. The range of the angle β affects the reliability of the bridging electrode 30 passing through the isolation trench 40 in the direction Y. The angle β being too small or too large is unfavorable for the deposition of the bridging electrode 30 on the isolation trench 40. Further, the bridging electrode 30 has the thickness h2 on the isolation trench 40, and the thickness h2 ranges from 0.5μm to 8μm. In the present embodiment, the angle β ranges from 65° to 85°, and the thickness h2 ranges from 1.5 μm to 3 μm.

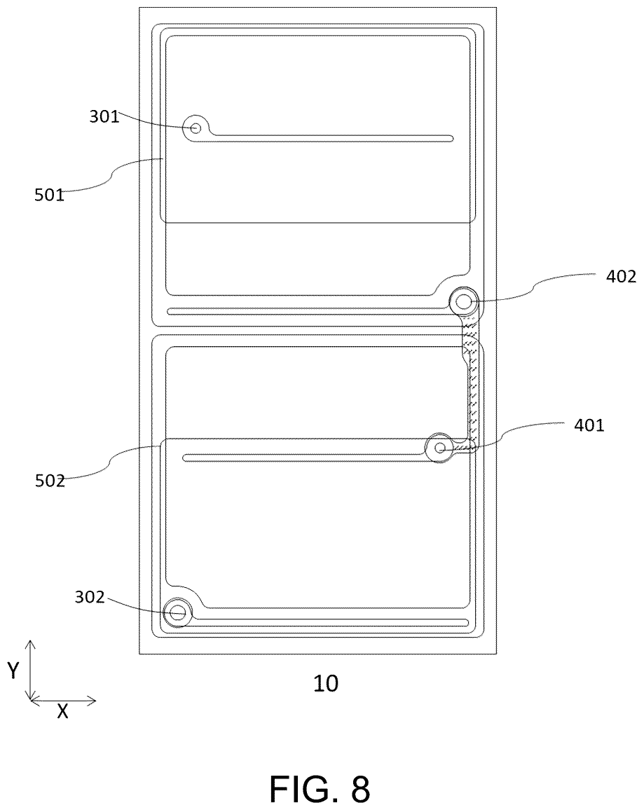

Since the top views of the present disclosure involve a relatively large number of structures, for ease of understanding, bond pad electrodes are schematically shown in FIG. 3, FIG. 4, FIG. 5, and FIG. 8. As shown in FIG. 8, in some embodiments, a first bond pad 501 is disposed on the first electrode 301, and a second bond pad 502 is disposed on the second electrode 302. The material of the first bond pad 501 and the second bond pad 502 is one or more of Ti/Al/Ni/Au/Pt/Sn.

As shown in FIG. 2, in some embodiments, a bonding layer 600 is also disposed on the substrate 100. The bonding layer 600 functions to bond the substrate 100 with the plurality of light-emitting units 20 together. The bonding layer 600 may be a metal bonding layer or an oxide bonding layer. In the present embodiment, the bonding layer 600 is an oxide. In some embodiments, the bonding layer 600 may also be roughened to obtain a better light-output effect.

As shown in FIG. 2, in some embodiments, an insulating layer 700 is further disposed outside the epitaxial structure 200. The insulating layer 700 may protect the epitaxial structure 200 and may cover the isolation trench 40 to better implement electrical isolation between the first light-emitting unit 21 and the second light-emitting unit 22. In some embodiments, the insulating layer 700 may be a single-layer structure, for example, magnesium fluoride or silicon nitride, may also be a double-layer structure, for example, a DBR reflector composed of SiO₂ and TiO₂, and may also be a multi-layer structure, for example, a combination of at least two of multiple structures such as magnesium fluoride, silicon nitride, SiO₂, TiO₂, ZnO₂, ZrO₂, and Cu₂O₃.

In some embodiments, a protective layer 800 (shaded portion in FIG. 2) is further disposed between the bridging electrode 30 and the epitaxial structure 200, which may prevent short circuits at the electrode, and the material may be one or more of magnesium fluoride, silicon nitride, or silicon oxide.

In some embodiments, the first electrode 301 or the second electrode 302 may have an extension portion, such as a finger electrode.

### Embodiment 2

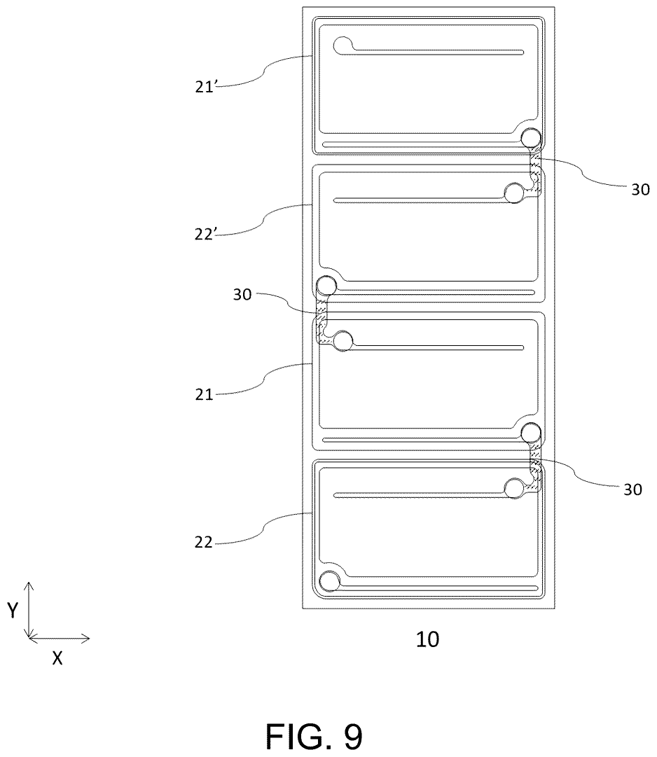

As shown in FIG. 3 and FIG. 9, in some embodiments, the light-emitting diode has 1 pair or 2 pairs of first light-emitting units 21 (21′) and second light-emitting units 22 (22′) adjacent to each other. In the present embodiment, as shown in FIG. 9, there are 2 pairs of first light-emitting units 21 (21′) and second light-emitting units 22 (22′) adjacent to each other. Of course, more light-emitting units may also be arranged according to requirements, and the present disclosure is not limited thereto.

### Embodiment 3

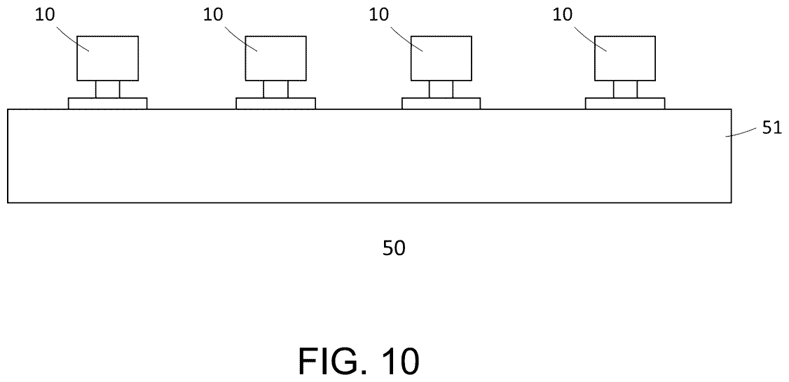

As shown in FIG. 10, the present disclosure further provides a light-emitting device 50. The light-emitting device 50 has a driving substrate 51. A plurality of light-emitting diodes 10 are disposed on the driving substrate 51, and the light-emitting diodes 10 are any one of the above-mentioned light-emitting diodes or combinations thereof.

In summary, the present disclosure provides the light-emitting diode 10. Compared with the bridging electrode 30 of a conventional light-emitting diode (as shown in FIG. 1), the present disclosure provides several embodiments, in which the bridging electrode 30 is disposed in the direction X, passes through the first mesa S1 of the second light-emitting unit 22, and covers a portion of the second mesa S2. In this way, the bridging electrode 30 may not only conduct electricity on the first mesa S1, but also transmit current on the second mesa S2. When the bridging electrode 30 on the first mesa S1 is damaged, the bridging electrode 30 may also carry out transmission to the second mesa S2 through the sidewall and continue to complete current transmission, which is equivalent to having an additional current transmission channel than a conventional light-emitting diode, thereby significantly improving the reliability of the light-emitting diode 10.

The present disclosure also provides the light-emitting device 50. The light-emitting device 50 is equipped with the above-mentioned light-emitting diode 10, and therefore also has the above-mentioned advantages.

Finally, it should be noted that: the above embodiments are only used to illustrate the technical solutions of the present disclosure, rather than to limit it; although the present disclosure has been described in detail with reference to the foregoing embodiments, those of ordinary skill in the art should understand that: modifications may still be made to the technical solutions described in the foregoing embodiments, or equivalent replacements may be made to some or all of the technical features therein; and these modifications or replacements do not cause the essence of the corresponding technical solutions to depart from the scope of the technical solutions of the embodiments of the present disclosure.

What is claimed is:

1. A light-emitting diode, comprising:
a substrate, comprising an upper surface;
wherein a plurality of light-emitting units are disposed on the upper surface of the substrate, the light-emitting units contain a first light-emitting unit and a second light-emitting unit adjacent to each other, an isolation trench is formed between the first light-emitting unit and the second light-emitting unit, the first light-emitting unit to the second light-emitting unit are arranged in a direction Y, and a direction perpendicular to the direction Y is a direction X;
the first light-emitting unit and the second light-emitting unit both contain an epitaxial structure, the epitaxial structure sequentially comprises, from top to bottom, a first semiconductor layer, an active layer, and a second semiconductor layer;
the first semiconductor layer has an upper surface, which is a first mesa;
the second semiconductor layer has an upper surface, and a portion of the upper surface of the second semiconductor layer not covered by the first semiconductor layer and the active layer is a second mesa;
the first light-emitting unit further contains a first electrode and a second port, the first electrode is disposed on the first mesa, and the second port is disposed on the second mesa;
the second light-emitting unit further contains a second electrode and a first port, the second electrode is disposed on the second mesa, and the first port is disposed on the first mesa;
a bridging electrode connects the first light-emitting unit and the second light-emitting unit, the bridging electrode connects the first port and the second port adjacent to each other along the direction Y;
in the second light-emitting unit, the bridging electrode passes through the first mesa along the direction X and covers a portion of the second mesa, and a portion of the bridging electrode covering the second mesa is an extension portion of the bridging electrode.

2. The light-emitting diode according to claim 1, wherein
a horizontal projection area of the extension portion of the bridging electrode on the second mesa accounts for 0.8% to 15% of a horizontal projection area of the second mesa.

3. The light-emitting diode according to claim 1, wherein
the second mesa where the extension portion of the bridging electrode is located has a width D in the direction X, the extension portion of the bridging electrode has a width d in the direction X, and a ratio of the width d to the width D ranges from 60% to 90%.

4. The light-emitting diode according to claim 1, wherein
the extension portion of the bridging electrode has a width d in the direction X, and the width d ranges from 4 μm to 60 μm.

5. The light-emitting diode according to claim 4, wherein
the second mesa where the extension portion of the bridging electrode is located has a width D in the direction X, and the width D ranges from 6 μm to 70 μm.

6. The light-emitting diode according to claim 1, wherein
a portion of the bridging electrode at the first mesa of the second light-emitting unit has a minimum width W in the direction X, and the minimum width W ranges from 1 μm to 30 μm.

7. The light-emitting diode according to claim 1, wherein
the isolation trench has a width g in the direction Y, and the width g ranges from 3 μm to 30 μm.

8. The light-emitting diode according to claim 1, wherein
the extension portion of the bridging electrode has a length L1 in the direction Y, and the length L1 ranges from 5 μm to 95 μm.

9. The light-emitting diode according to claim 8, wherein
the bridging electrode has a length L2 in the direction Y, and the length L2 ranges from 18 μm to 110 μm.

10. The light-emitting diode according to claim 1, wherein
the second light-emitting unit has a first sidewall between the first mesa and the second mesa, an angle α is formed between the first sidewall and a horizontal plane, and the angle α ranges from 35° to 75°.

11. The light-emitting diode according to claim 1, wherein
the extension portion of the bridging electrode has a thickness h1 on the second mesa, and the thickness h1 ranges from 0.5 μm to 8 μm.

12. The light-emitting diode according to claim 1, wherein
a second sidewall is provided between the second mesa of the second light-emitting unit and the isolation trench, an angle β is formed between the second sidewall and a horizontal plane, and the angle β ranges from 50° to 85°.

13. The light-emitting diode according to claim 1, wherein
the bridging electrode has a thickness h2 on the isolation trench, and the thickness h2 ranges from 0.5 μm to 8 μm.

14. The light-emitting diode according to claim 1, wherein
the light-emitting diode has one pair or two pairs of the first light-emitting unit and the second light-emitting unit disposed adjacent to each other.

15. The light-emitting diode according to claim 1, wherein
a bonding layer is further disposed on the substrate.

16. The light-emitting diode according to claim 1, wherein
an insulating layer is further disposed outside the epitaxial structure, and the insulating layer is a single-layer or multi-layer structure.

17. The light-emitting diode according to claim 1, wherein
a first bond pad is disposed on the first electrode, and a second bond pad is disposed on the second electrode.

18. The light-emitting diode according to claim 1, wherein
at least one of the first electrode and the second electrode has an expanding portion.

19. The light-emitting diode according to claim 1, wherein
a material of the bridging electrode is one of Ti, Pt, Au, or a combination of at least two of the above.

20. A light-emitting device, comprising the light-emitting diode according to claim 1.
